(19) United States
(12) Patent Application Publication
(10) Pub. No.: US 2024/0087846 A1
(43) Pub. Date: Mar. 14, 2024

(54) PLASMA PROCESSING APPARATUS AND RF SYSTEM

(71) Applicant: Tokyo Electron Limited, Tokyo (JP)

(72) Inventors: Toshiharu WADA, Miyagi (JP); Weifan CHEN, Tokyo (JP); Tangkuei WANG, Miyagi (JP)

(73) Assignee: Tokyo Electron Limited, Tokyo (JP)

(21) Appl. No.: 18/512,566

(22) Filed: Nov. 17, 2023

Related U.S. Application Data
(63) Continuation of application No. PCT/JP2022/019684, filed on May 9, 2022.

(30) Foreign Application Priority Data
May 19, 2021 (JP) 2021-084713

(51) Int. Cl. H01J 37/32; H01L 21/02; H01L 21/3065

(52) U.S. Cl. CPC H01J 37/32091; H01J 37/32532; H01L 21/02274; H01L 21/3065; H01J 2237/334

(57) ABSTRACT

A plasma processing apparatus includes: a chamber; a substrate support including a lower electrode; an upper electrode disposed above the substrate support; a first RF power supply that is electrically connected to the upper electrode and generates a first RF signal, in which the first RF signal has a first power level during a first state within a repeating period and a zero power level during second to fourth states within the repeating period; a second RF power supply that is electrically connected to the lower electrode and generates a second RF signal, in which the second RF signal has a zero power level during the first and second states, a second power level during the third state, and a third power level during the fourth state; and a DC power supply that is electrically connected to the upper electrode and generates a DC signal.

### CROSS-REFERENCE TO RELATED APPLICATIONS

This application is a Continuation of International Patent Application No. PCT/JP2022/019684, filed on May 9, 2022, which claims priority from Japanese Patent Application No. 2021-084713, filed on May 19, 2021, all of which are incorporated herein in their entireties by reference.

### TECHNICAL FIELD

The present disclosure relates to a plasma processing apparatus and an RF system.

### BACKGROUND

As the miniaturization of semiconductors progresses, an etching process with a high aspect ratio is required. Thus, a technique called an atomic layer etching (ALE) has been proposed, which repeats an etchant deposition step and an ion irradiation step, thereby accelerating an etching. In the ALE, the deposition step and the ion irradiation step are separated from each other by switching processing gases used for the steps. Further, in order to prevent the occurrence of standing waves of multiple radio-frequency powers supplied into a processing container of a plasma processing apparatus, it has been proposed to perform a control for causing a predetermined phase difference between pulse waves of a plasma generation radio-frequency power and a bias radio-frequency power (e.g., Japanese Patent Laid-Open Publication No. 2016-157735).

### SUMMARY

According to an aspect of the present disclosure, a plasma processing apparatus includes: a chamber; a substrate support disposed in the chamber and including a lower electrode; an upper electrode disposed above the substrate support; a first RF power supply that is electrically connected to the upper electrode and generates a first RF signal, in which the first RF signal has a first power level during a first state within a repeating period and a zero power level during a second state, a third state, and a fourth state within the repeating period; a second RF power supply that is electrically connected to the lower electrode and generates a second RF signal, in which the second RF signal has a zero power level during the first and second states, a second power level during the third state, and a third power level during the fourth state; and a DC power supply that is electrically connected to the upper electrode and generates a DC signal.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a plasma processing system according to an embodiment of the present disclosure.

FIG. 2 is a view schematically illustrating an example of a structure of a substrate subjected to an etching by a plasma processing apparatus according to the present embodiment.

FIGS. 3A and 3B are views illustrating an example of one cycle of an RF signal in the present embodiment and a Reference Example.

FIGS. 4A and 4B are views illustrating an example of one cycle of an RF signal in the present embodiment and a Reference Example.

FIGS. 5A and 5B are views illustrating an example of a DC signal in the present embodiment.

FIGS. 6A and 6B are views illustrating an example of experimental results in the present embodiment and a Reference Example.

FIGS. 7A and 7B are views illustrating an example of a shape control model in the present embodiment and a Reference Example.

FIGS. 8A and 8B are views illustrating an example of a selection ratio improvement model in the present embodiment and a Reference Example.

FIG. 9 is a view illustrating an example of an etching amount in each phase.

FIG. 10 is a view illustrating an example of the luminous intensity in each phase.

FIG. 11 is a view illustrating an example of a comparison of an etching amount between the present embodiment and a Reference Example.

FIG. 12 is a view illustrating an example of one cycle of an RF signal in a modification.

FIGS. 13A and 13B are views illustrating an example of experimental results in a case where the distribution of an RF power of LF is changed.

FIG. 14 is a view illustrating an example of a graph representing trend data in a case where the distribution of an RF power of LF is changed.

FIG. 15 is a view illustrating an example of a shape control model in a modification.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a plasma processing apparatus and an RF system of the present disclosure will be described in detail based on the drawings. The present disclosure is not limited to the embodiments described herein below.

In an etching process for a high aspect ratio, for example, when a radio-frequency power is supplied in the form of continuous waves (CW), the shape of the bottom of a recess formed in an etching target film (bottom shape) becomes rectangular, which reduces the process time, but causes an occurrence of an etching failure (e.g., deterioration of an etching rate) resulting in a reduction of the selection ratio. Here, the selection ratio is an etching rate of an etching target film/an etching rate of a mask. Meanwhile, when the ALE is used, the etching rate and the selection ratio improve, but the bottom shape becomes tapered, which increases the process time. That is, the improvement of etching rate, selection ratio, and shape controllability, and the reduction of process time stand in a trade-off relationship with each other. Thus, it is expected to perform an etching, which may resolve the trade-off relationship and implement not only the improvement of selection ratio, etching rate, and shape controllability, but also the reduction of process time.

[Configuration of Plasma Processing System]

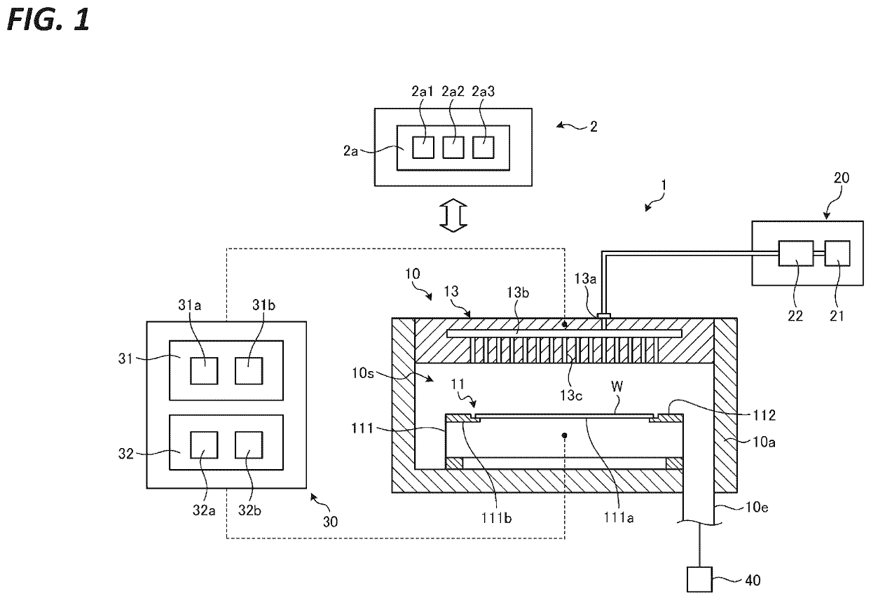

Hereinafter, an example of a configuration of a plasma processing system will be described. FIG. 1 is a view illustrating an example of a plasma processing system according to an embodiment of the present disclosure. As illustrated in FIG. 1, the plasma processing system includes a capacitively coupled plasma processing apparatus 1 and a controller 2. The plasma processing system is an example of a substrate processing apparatus. The capacitively coupled plasma processing apparatus 1 includes a plasma processing chamber 10, a gas supply 20, a power supply 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a showerhead 13. The substrate support 11 is disposed inside the plasma processing chamber 10. The showerhead 13 is disposed above the substrate support 11. In an embodiment, the showerhead 13 makes up at least a portion of the ceiling of the plasma processing chamber 10. The plasma processing chamber 10 has a plasma processing space 10s defined by the showerhead 13, the sidewall 10a of the plasma processing chamber 10, and the substrate support 11. The plasma processing chamber 10 includes at least one gas supply port for supplying at least one processing gas to the plasma processing space 10s, and at least one gas discharge port for discharging a gas from the plasma processing space. The sidewall 10a is grounded. The showerhead 13 and the substrate support 11 are electrically insulated from the housing of the plasma processing chamber 10.

The substrate support 11 includes a main body 111 and a ring assembly 112. The main body 111 has a central region (substrate supporting surface) 111a for supporting a substrate (wafer) W, and an annular region (ring supporting surface) 111b for supporting the ring assembly 112. The annular region 111b of the main body 111 surrounds the central region 111a of the main body 111 in a plan view. The substrate W is placed on the central region 111a of the main body 111, and the ring assembly 112 is disposed on the annular region 111b of the main body 111 to surround the substrate W placed on the central region 111a of the main body 111. In an embodiment, the main body 111 includes a base and an electrostatic chuck. The base includes a conductive member. The conductive member of the base functions as a lower electrode. The electrostatic chuck is disposed on the base. The upper surface of the electrostatic chuck serves as the substrate supporting surface 111a. The ring assembly 112 includes one or a plurality of annular members. At least one of the one or more annular members is an edge ring. Although not illustrated, the substrate support 11 may include a temperature adjustment module configured to adjust at least one of the electrostatic chuck, the ring assembly 112, and the substrate W to a target temperature. The temperature adjustment module may include a heater, a heat transfer medium, a flow path, or a combination thereof. A heat transfer fluid such as brine and a gas flows through the flow path. The substrate support 11 may include a heat transfer gas supply configured to supply a heat transfer gas to the space between the rear surface of the substrate W and the substrate supporting surface 111a.

The showerhead 13 is configured to introduce at least one processing gas from the gas supply 20 into the plasma processing space 10s. The showerhead 13 has at least one gas supply port 13a, at least one gas diffusion space 13b, and a plurality of gas introduction ports 13c. The processing gas supplied to the gas supply port 13a passes through the gas diffusion space 13b and is introduced into the plasma processing space 10s from the plurality of gas introduction ports 13c. Further, the showerhead 13 includes a conductive member. The conductive member of the showerhead 13 functions as an upper electrode. Further, the gas introduction unit may include one or a plurality of side gas injectors (SGI) attached to one or a plurality of openings formed in the sidewall 10a, in addition to the showerhead 13.

The gas supply 20 may include at least one gas source 21 and at least one flow controller 22. In an embodiment, the gas supply 20 is configured to supply at least one processing gas from its corresponding gas source 21 to the showerhead 13 via its corresponding flow controller 22. Each flow controller 22 may include, for example, a mass flow controller or a pressure-controlled flow controller. The gas supply 20 may further include one or more flow modulation devices that modulate or pulse the flow of at least one processing gas.

The power supply 30 includes an RF power supply 31 coupled to the plasma processing chamber 10 via at least one impedance matching circuit. The RF power supply 31 is configured to supply at least one RF signal (RF power) such as a source RF signal or a bias RF signal, to the conductive member of the substrate support 11 and/or the conductive member of the showerhead 13. Thus, a plasma is formed from at least one processing gas supplied into the plasma processing space 10s. Accordingly, the RF power supply 31 may function as at least a portion of a plasma generator configured to generate a plasma from one or more processing gases in the plasma processing chamber 10. Further, by supplying the bias RF signal to the conductive member of the substrate support 11, a bias potential is generated in the substrate W, so that ion components in the formed plasma may be drawn into the substrate W.

In an embodiment, the RF power supply 31 includes a first RF generator 31a and a second RF generator 31b. The first RF generator 31a is coupled to the conductive member of the substrate support 11 and/or the conductive member of the showerhead 13 via at least one impedance matching circuit, and configured to generate a source RF signal (source RF power) for plasma generation. In an embodiment, the source RF signal has a frequency in the range of 13 MHz to 150 MHz. In an embodiment, the first RF generator 31a may be configured to generate a plurality of source RF signals with different frequencies. The generated one or more source RF signals are supplied to the conductive member of the substrate support 11 and/or the conductive member of the showerhead 13. The second RF generator 31b is coupled to the conductive member of the substrate support 11 via at least one impedance matching circuit, and configured to generate a bias RF signal (bias RF power). In an embodiment, the bias RF signal has a lower frequency than that of the source RF signal. In an embodiment, the bias RF signal has a frequency in the range of 400 kHz to 13.56 MHz. In an embodiment, the second RF generator 31b may be configured to generate a plurality of bias RF signals with different frequencies. The generated one or more bias RF signals are supplied to the conductive member of the substrate support 11. In various embodiments, at least one of the source RF signal and the bias RF signal may be pulsed.

The power supply 30 may include a DC power supply 32 coupled to the plasma processing chamber 10. The DC power supply 32 includes a first DC generator 32a and a second DC generator 32b. In an embodiment, the first DC generator 32a is connected to the conductive member of the substrate support 11, and configured to generate a first DC signal. The generated first DC signal is supplied to the conductive member of the substrate support 11. In an embodiment, the first DC signal may be supplied to another electrode such as an electrode of the electrostatic chuck. In an embodiment, the second DC generator 32b is connected to the conductive member of the showerhead 13, and configured to generate a second DC signal. The generated second DC signal is supplied to the conductive member of the showerhead 13. In various embodiments, at least one of the first and second DC signals may be pulsed. The first and second DC generators 32a and 32b may be provided in addition to the RF power supply 31, and the first DC generator 32a may be provided in place of the second RF generator 31b.

The exhaust system 40 may be connected to a gas discharge port 10e formed at, for example, the bottom of the plasma processing chamber 10. The exhaust system 40 may include a pressure regulation valve and a vacuum pump. The pressure inside the plasma processing space 10s is regulated by the pressure regulation valve. The vacuum pump may include a turbo molecular pump, a dry pump, or a combination thereof.

The controller 2 processes computer-executable commands for causing the plasma processing apparatus 1 to execute various processes described herein. The controller 2 may be configured to control each component of the plasma processing apparatus 1 to perform the various processes described herein. In an embodiment, a portion of the controller 2 or the entire controller 2 may be included in the plasma processing apparatus 1. The controller 2 may include, for example, a computer 2a. The computer 2a may include, for example, a processor (central processing unit; CPU) 2a1, a storage 2a2, and a communication interface 2a3. The processor 2a1 may be configured to perform various control operations based on programs stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

[Processing Target Substrate]

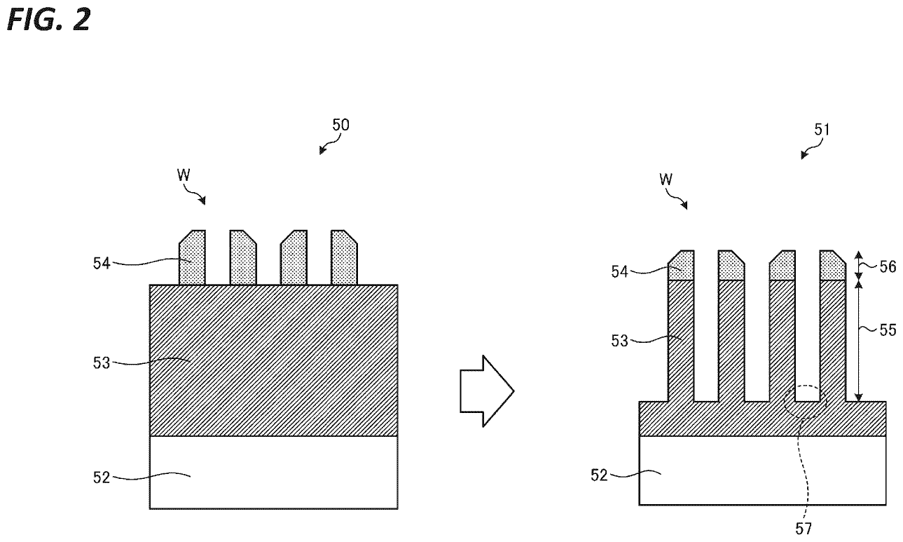

Next, a substrate to be etched will be described using FIG. 2. FIG. 2 is a view schematically illustrating an example of the structure of a substrate subjected to an etching by the plasma processing apparatus. FIG. 2 illustrates an unprocessed state 50 and a processed state 51 of a substrate W. The substrate W includes a silicon oxide film 53 and a mask 54 on a silicon substrate 52. The silicon oxide film 53 is an etching target film. The mask 54 is a silicon nitride film, and has predetermined patterned openings, for example, comb-shaped openings. The pitch between adjacent openings is, for example, 25 nm to 30 nm, and the target value of the line critical dimension (CD) is, for example, 10 nm. As represented in the state 51, the etching of the silicon oxide film 53 of the openings of the mask 54 is terminated before a recess reaches the silicon substrate 52, and a partial etching is performed such that the aspect ratio of the recess in the silicon oxide film 53 is 7 or higher. At this time, for example, it is required to improve the selection ratio, which is the relationship between an etching depth 55 and a residual amount 56 of the mask 54, or the shape controllability of a recess bottom shape 57. Thus, in the present embodiment, during a supply pattern in which the source RF signal and the bias RF signal of the radio-frequency power are supplied in pulses, the power level of the bias RF signal is controlled, thereby improving the selection ratio, the etching rate, and the shape controllability, and further, reducing the process time as compared to the ALE using the gas switching method.

[Supply Pattern of RF Signal]

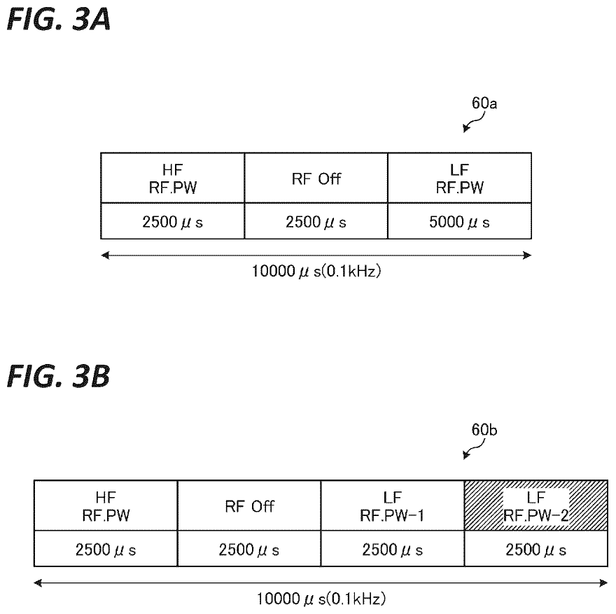

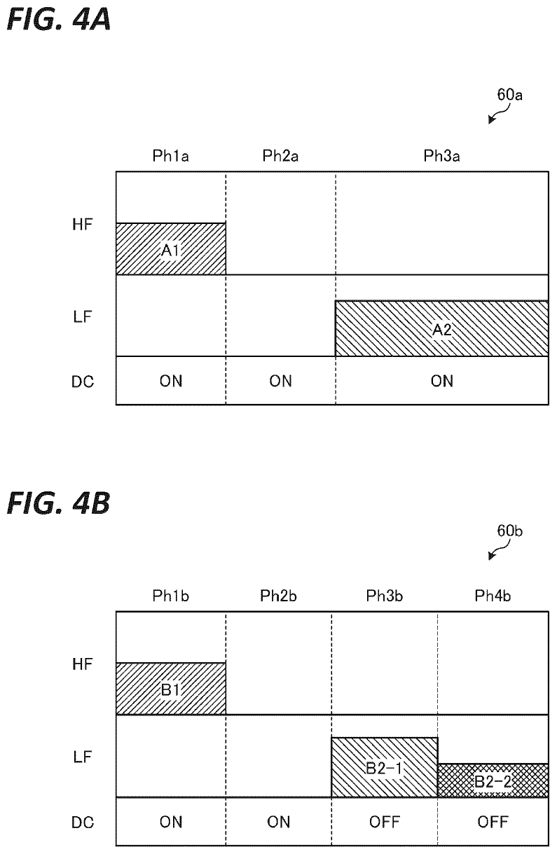

Next, the supply pattern of the RF signal (RF power) in the etching process will be described using FIGS. 3A, 3B, 4A, and 4B through a comparison with a Reference Example. FIGS. 3A, 3B, 4A, and 4B are views illustrating an example of one cycle of the RF signal in the present embodiment and the Reference Example. FIG. 3A illustrates a supply pattern 60a for the Reference Example, and FIG. 3B illustrates a supply pattern 60b for the present embodiment. In the present embodiment, a deposition step and an etching step are repeated by repeating the supply pattern 60b. One cycle of the supply pattern 60b is repeated at, for example, 10,000 μs (0.1 kHz). One cycle of the supply pattern 60b may be, for example, an arbitrary cycle equal to or less than 100 ms (10 Hz). For example, when defining one cycle of the supply pattern 60b as a repeating period with a repeating frequency, the repeating period may have the repeating frequency in the range of 10 Hz to 100 kHz (100 ms to 10 μs). In the descriptions and the drawings hereinafter, the source RF signal may be referred to as a high frequency (HF), the bias RF signal may be referred to as a low frequency (LF), and the second DC signal may be referred to as DC. Further, the period during which the RF signal is being supplied may be referred to as “RF.PW,” and the period during which the RF signal is stopped may be referred to as “RF Off.”

The supply pattern 60a of the Reference Example corresponds to a case where the power level of the bias RF signal is not changed. The supply pattern 60a has one cycle of 10,000 μs (0.1 kHz) similar to the supply pattern 60b, and is divided into three phases including the supply of HF for 2,500 μs, the stop of HF and LF for 2,500 μs, and the supply of LF for 5,000 μs in this order from the beginning. Meanwhile, the supply pattern 60b of the present embodiment is divided into four phases including the supply of HF at a first power level for 2,500 μs, the stop of HF and LF for 2,500 μs, the supply of LF at a second power level for 2,500 μs (RF.PW-1), and the supply of LF at a third power level (RF.PW-2) for 2,500 μs in this order from the beginning.

FIGS. 4A and 4B illustrate the power levels and ON/OFF of DC in each phase of the supply patterns 60a and 60b. Further, in the descriptions and the drawings hereinafter, the phases of the supply pattern 60a will be referred to as phases Ph1a, Ph2a, and Ph3a, respectively, from the beginning, and the phases of the supply pattern 60b will be referred to phases Ph1b, Ph2b, Ph3b, and Ph4b, respectively, from the beginning. The phases Ph1a and Ph1b correspond to the deposition step, and the phases Ph3a, Ph3b, and Ph4b correspond to the etching step. The phases Ph1b, Ph2b, Ph3b, and Ph4b are examples of first, second, third, and fourth states within the repeating period, respectively.

In the supply pattern 60a illustrated in FIG. 4A, HF is supplied at a power level A1 during the phase Ph1a, HF and LF are stopped during the phase Ph2a, and LF is supplied at a power level A2 during the phase Ph3a. Further, DC is supplied during the phases Ph1a to Ph3a (represented as “ON” in FIG. 4A). Meanwhile, in the supply pattern 60b illustrated in FIG. 4B, HF is supplied at a power level B1 (a first power level) during the phase Ph1b, HF and LF are stopped during the phase Ph2b, LF is supplied at a power level B2-1 (a second power level) during the phase Ph3b, and LF is supplied at a power level B2-2 (a third power level) during the phase Ph4b. At this time, the power level B2-1 (the second power level) is higher than the power level B2-2 (the third power level). Further, DC is supplied during the phases Ph1b and Ph2b (represented as “ON” in FIG. 4B), and is stopped during the phases Ph3b and Ph4b (represented as “OFF” in FIG. 4B). That is, as compared to the supply pattern 60a, in the supply pattern 60b, the power level is changed in two steps during the supply of LF, and the supply of DC is stopped in the etching step. The power level during the supply of LF may not be changed in two steps, but may be changed in three or more steps or may be changed continuously.

Here, the phases Ph1b to Ph4b of the supply pattern 60b are an example of the repeating period as described above, and the proportions of the phases Ph1b to Ph4b may be changed within the repeating period. In the supply pattern 60b illustrated in FIG. 4B, the phases Ph1b to Ph4b are equally divided to each occupy 25%. In this case, it may be said that the period of the phase Ph1b is the same as the period of the phase Ph2b. It may also be said that the period of the phase Ph3b is the same as the period of the phase Ph4b.

Meanwhile, when changing the proportions of the phases Ph1b to Ph4b, for example, the period of the phase Ph1b may be longer or shorter than the period of the phase Ph2b. Similarly, the period of the phase Ph3b may be longer or shorter than the period of the phase Ph4b. The period of the phase Ph2b may be 50% or less of the repeating period. The range of the proportions of the phases Ph1b to Ph4b may be in the range of 5% to 90% of the repeating period. Both the length of the repeating period and the proportions of the phases may be changed, and in this case, the periods of the phases Ph1b to Ph4b may be in the range of 0.5 microseconds to 90 milliseconds (0.5 μs to 90 ms). The change of the length and the proportions of the periods of the phases Ph1b to Ph4b may be combined with a modification to be described later.

As for the relationship between the periods of the phases Ph1b and Ph2b, when the period of the phase Ph2b is longer than the period of the phase Ph1b, the plasma density decreases significantly, so that the radical/ion ratio increases. Further, when the period of the phase Ph2b is longer than the period of the phase Ph1b, the transport of radicals to the bottom of a recess (trench) is accelerated, so that the etching progresses more easily, and the etching rate improves. Meanwhile, when the period of the phase Ph2b is shorter than the period of the phase Ph1b, the amount of deposit on the mask 54 increases, so that the selectivity ratio may improve.

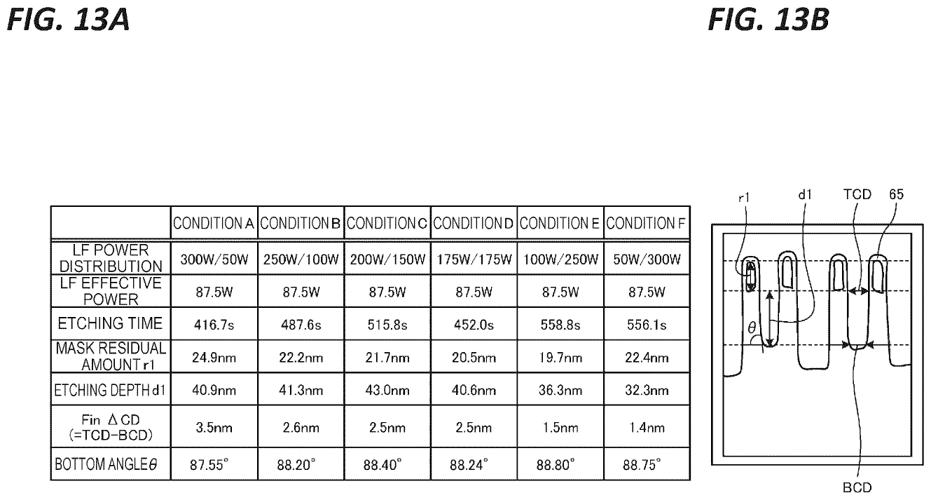

When the periods of the phases Ph3b and Ph4b are the same, the bottom shape of a recess (trench) may be controlled by controlling the power level B2-1 of the phase Ph3b and the power level B2-2 of the phase Ph4b. When the power level B2-1 of the phase Ph3b is higher than the power level B2-2 of the phase Ph4b, the bottom shape of a recess (trench) becomes tapered. Meanwhile, when the power level B2-1 of the phase Ph3b is lower than the power level B2-2 of the phase Ph4b (see the modification to be described later), the bottom shape of a recess (trench) becomes rectangular (vertical). Thus, when the periods of the phases Ph3b and Ph4b are the same, the bottom shape of a recess (trench) may be controlled by controlling the power level B2-1 of the phase Ph3b and the power level B2-2 of the phase Ph4b. FIGS. 13A and 13B to be described later illustrate experimental results.

As for the relationship between the periods of the phases Ph3b and Ph4b, when the period of the phase Ph3b is longer than the period of the phase Ph4b, the bottom shape of a recess (trench) becomes rectangular (vertical). Meanwhile, when the period of the phase Ph3b is shorter than the period of the phase Ph4b, the bottom shape of a recess (trench) becomes tapered. That is, the bottom shape of a recess (trench) may be controlled by controlling the periods of the phases Ph3b and Ph4b.

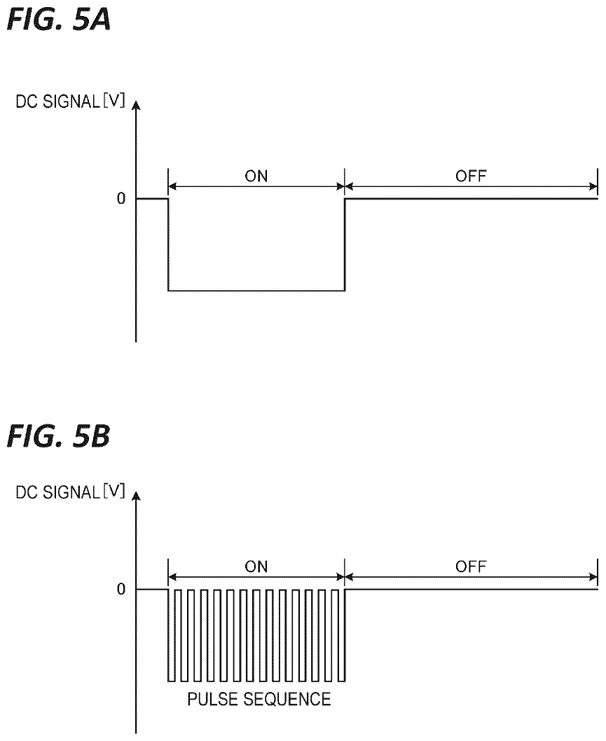

Next, descriptions will be made on the second DC signal (hereinafter, simply referred to as the DC signal) supplied to the conductive member of the showerhead 13 (e.g., the upper electrode), using FIGS. 5A and 5B. FIGS. 5A and 5B are views illustrating an example of the DC signal in the present embodiment. In an embodiment, the DC signal has a constant negative voltage level during the ON period as illustrated in FIG. 5A. In an embodiment, the DC signal has a sequence of multiple negative pulses during the ON period as illustrated in FIG. 5B. For example, in the phase Ph1b, the sequence of multiple negative pulses overlaps with HF of the upper electrode.

In the supply pattern 60b illustrated in FIG. 4B, for example, the DC signal has a first voltage level in the phases Ph1b and Ph2b, and has a second voltage level in the phases Ph3b and Ph4b. At this time, for example, it is assumed that the first and second voltage levels have the relationship of the absolute value of the first voltage level>the absolute value of the second voltage level. That is, the DC signal has the first voltage level with the negative polarity during the phases Ph1b and Ph2b and has the second voltage level during the phases Ph3b and Ph4b, and the absolute value of the second voltage level is smaller than the absolute value of the first voltage level.

Further, in the supply pattern 60b illustrated in FIG. 4B, the first voltage level of the DC signal may be set to, for example, −50 V to −2,500 V, and the second voltage level of the DC signal may be set to, for example, 0 V (zero voltage level). In this case, the first voltage level has a pulse frequency in the range of 1 kHz to 100 kHz. That is, the first voltage level has a sequence of negative DC pulses having the pulse frequency in the range of 1 kHz to 100 kHz. The DC signal may be, for example, a signal having a constant negative non-pulsed voltage level in the phases Ph1b to Ph4b.

In this way, the DC signal is supplied during the phases Ph1b and Ph2b, so that the composition ratio of carbon in a CF deposit, which is a reaction product (e.g., deposit), may be increased. That is, it is possible to contribute to the improvement of the selection ratio of the mask and the controllability of CD.

### EXPERIMENT RESULTS

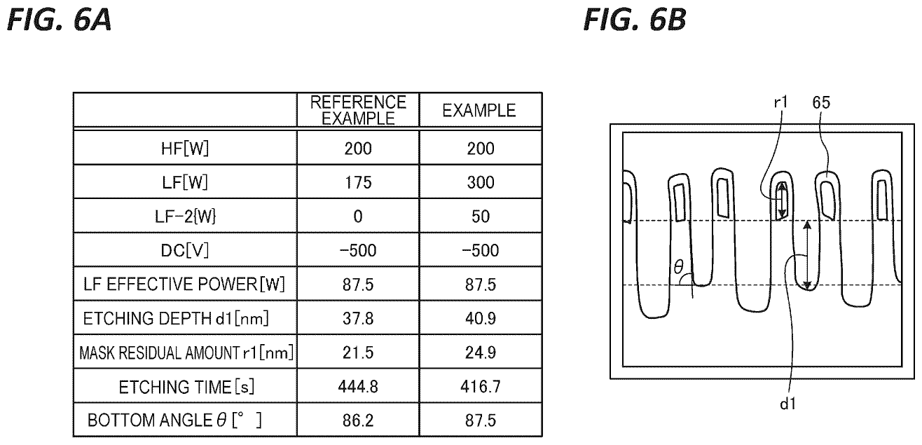

Next, experimental results will be described using FIGS. 6A and 6B. FIGS. 6A and 6B are views illustrating an example of experimental results in the present embodiment and the Reference Example. FIG. 6A illustrates experimental results in the Reference Example corresponding to the supply pattern 60a and an Example corresponding to the supply pattern 60b. FIG. 6B illustrates measurement parts for the etching depth d1, the mask residual amount r1, and the bottom angle θ. Further, in FIG. 6B, an SiON layer 65, which is an oxidized layer of the silicon nitride film, is formed around the mask (SiN). In addition, below are the used process conditions. In FIG. 6A, the power level of LF is represented in the LF field (the second power level) and the LF-2 field (the third power level), and “0” is described in the LF-2 field when the power level is one step. The LF effective power is the same in the Reference Example and the Example.

<Process Conditions>
Pressure in plasma processing chamber 10: 25 mTorr (3.33 Pa)
Temperature: 133° C.
Power of source RF signal (60 MHz): 200 W (pulse)
Power of bias RF signal (12.88 MHz): Reference Example: 175 W (pulse)
   Example: 300 W/50 W (pulse)
Voltage of second DC signal: −500 V
Pulse frequency: 0.1 kHz
Pulse duty: HF/LF/LF offset=25/50/50%
Flow rate ratio of processing gas (e.g., C₄F₆/O₂/Ar): 0.5/0.47/100

As illustrated in FIG. 6A, the etching depth d1 is 40.9 nm in the Example, which is deeper than 37.8 nm in the Reference Example. The mask residual amount r1 is 24.9 nm in the Example, which represents the high mask selection ratio as compared to 21.5 nm in the Reference Example. The etching time is 416.7 seconds in the Example, which is reduced as compared to 444.8 seconds in the Reference Example. The bottom angle θ is 87.5° in the Example, which is more vertical as compared to 86.2° in the Reference Example, and thus, it may be seen that the bottom shape of the Example is more rectangular than the Reference Example. Thus, in the supply pattern according to the present embodiment, the selectivity is higher than the supply pattern with the constant LF power level, the bottom shape is closer to the rectangular shape, and the process time may be reduced.

[Analysis Result]

<Shape Control Model>

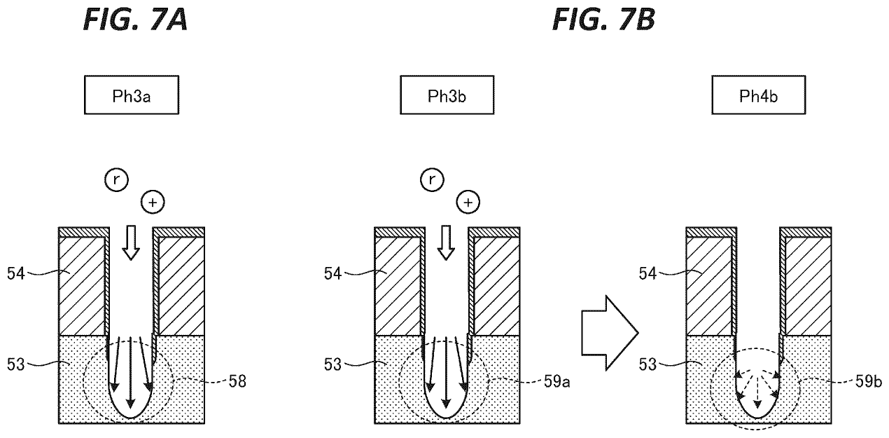

Next, a shape control model will be described using FIGS. 7A and 7B. FIGS. 7A and 7B are views illustrating an example of a shape control model in the present embodiment and the Reference Example. FIG. 7A illustrates a shape control model in the phase Ph3a of the Reference Example. In the phase Ph3a, Ar ions generated by second plasma are drawn into the bottom of the recess of the silicon oxide film 53 through the opening of the mask 54 by the bias potential, so that the etching progresses as represented in a state 58.

FIG. 7B illustrates a shape control model in the phases Ph3b and Ph4b of the Example. In the phase Ph3b, the Ar ions generated by the second plasma are drawn into the bottom of the recess of the silicon oxide film 53 through the opening of the mask 54 by the bias potential, so that the etching progresses as represented in a state 59a. In the subsequent phase Ph4b, since the power level of the bias RF signal decreases, the ion energy of the Ar ions generated by the second plasma decreases, and further, the incident angle increases, so that the shape of the bottom of the recess of the silicon oxide film 53 (bottom shape) may be widened, and the bottom shape may be made rectangular (vertical shape of the wall surface), as represented in the state 59a.

<Selection Ratio Improvement Model>

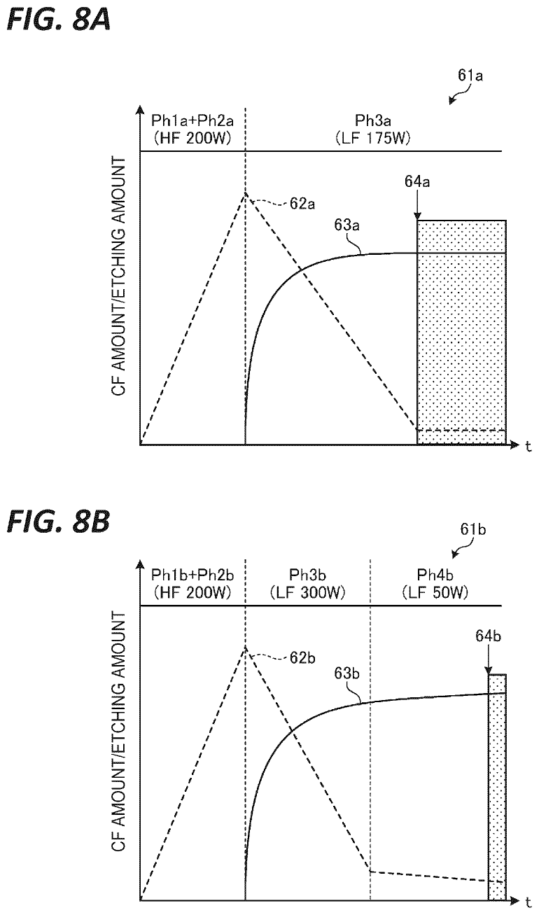

Next, a selection ratio improvement model will be described using FIGS. 8A and 8B. FIGS. 8A and 8B are views illustrating an example of a selection ratio improvement model in the present embodiment and the Reference Example. FIGS. 8A and 8B illustrate the relationship between the amount of CF, which is the reaction product (e.g., deposit) adhering to the surface of the mask 54, and the etching amount of CF within one cycle of the supply patterns 60a and 60b, respectively. The graph 61a illustrated in FIG. 8A represents the case of the supply pattern 60a of the Reference Example. In the phases Ph1a+Ph2a, the CF amount represented by the graph 62a increases, and the etching amount represented by the graph 63a is zero. In the subsequent phase Ph3a, the CF amount decreases as the etching amount increases, and at the time point 64a, the CF adhering to the surface of the mask 54 is removed, which damages the mask 54.

The graph 61b illustrated in FIG. 8B represents the case of the supply pattern 60b of the present embodiment. In the phases Ph1b+Ph2b, the CF amount represented by the graph 62b increases, and the etching amount represented by the graph 63b is zero. In the subsequent phase Ph3b, the CF amount decreases as the etching amount increases, but at the end time point of the phase Ph3b, the CF remains slightly. In the subsequent phase Ph4b, since the power level of the bias RF signal decreases so that the ion energy of the Ar ions decreases, the remaining CF amount decreases gently, and at the time point 64b, the CF adhering to the surface of the mask 54 is removed, which damages the mask 54. Upon comparing the graphs 61a and 61b, it may be seen that the supply pattern 60b of the present embodiment damages the mask 54 less, as compared to the supply pattern 60a of the Reference Example. That is, the supply pattern 60b of the present embodiment may improve the selection ratio, as compared to the supply pattern 60a of the Reference Example.

<Behavior During Supply of RF Signal>

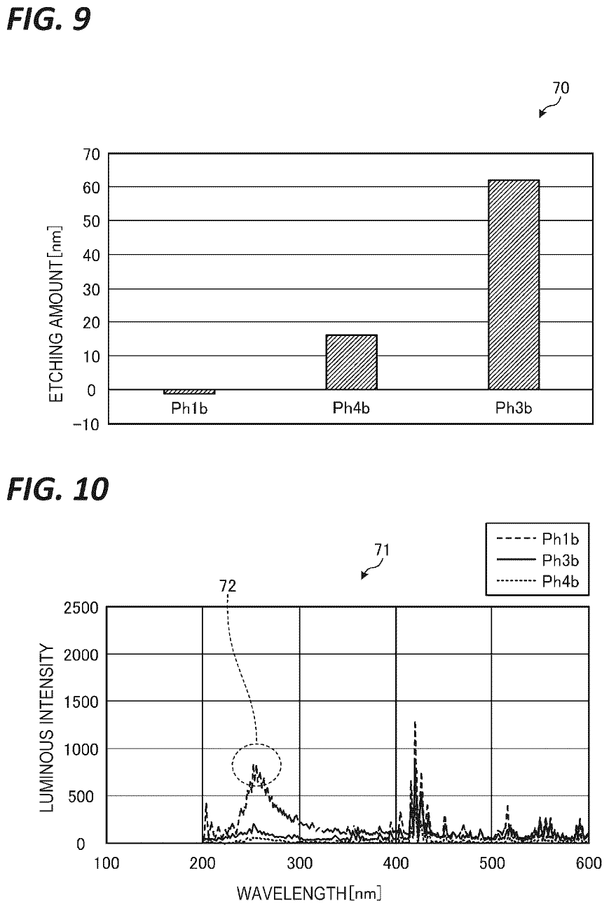

Next, descriptions will be made on behaviors in each phase of the supply pattern 60b of the present embodiment, using FIGS. 9 and 10. FIG. 9 is a view illustrating an example of the etching amount in each phase. The graph 70 illustrated in FIG. 9 represents the etching amount of the silicon oxide film 53 for the phases Ph1b, Ph3b, and Ph4b during which HF or LF is supplied, in the supply pattern 60b. As represented in the graph 70, since the etching of the silicon oxide film 53 does not progress in the phase Ph1b, it may be seen that the contribution of the phase Ph1b to the etching is low. Meanwhile, since the etching of the silicon oxide film 53 progresses in the phases Ph3b and Ph4b, it may be seen that the contribution of the phases Ph3b and Ph4b to the etching is high. Further, it may be seen that the etching amount of the silicon oxide film 53 in the phase Ph3b with the high power level of the bias RF signal is larger than the etching amount of the silicon oxide film 53 in the phase Ph4b with the low power level of the bias RF signal.

FIG. 10 is a view illustrating an example of the luminous intensity in each phase. The graph 71 illustrated in FIG. 10 represents the luminous intensity for the phases Ph1b, Ph3b, and Ph4b during which HF or LF is supplied, in the supply pattern 60b. As represented in the region 72 of the graph 71, since the CF luminescence is high in the phase Ph1b, it may be seen that the contribution to the deposit generation is high. Meanwhile, since the CF luminescence is low in the phases Ph3b and Ph4b, it may be seen that the contribution to the deposit generation is low.

<Verification of Etching Rate>

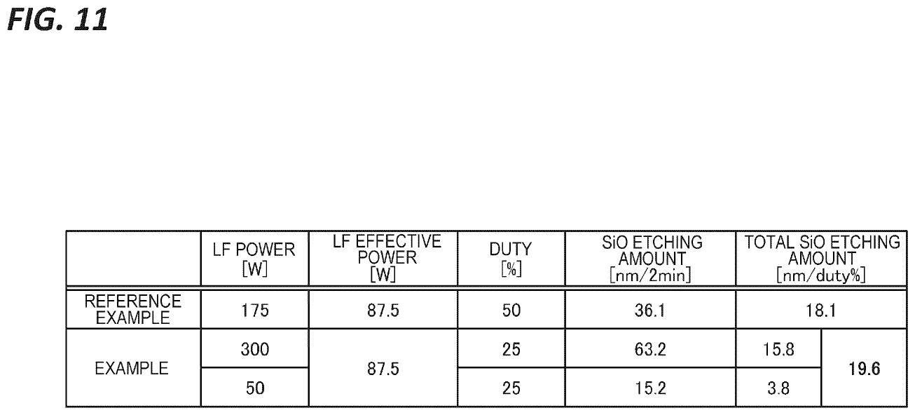

Next, the etching rate will be described using FIG. 11. FIG. 11 is a view illustrating an example of a comparison of an etching amount between the present embodiment and the Reference Example. As illustrated in FIG. 11, the LF effective power is the same in the Reference Example and the Example according to the present embodiment, but the SiO etching amount differs according to the LF power. In the Reference Example, when the LF power is 175 W (e.g., the phase Ph3a), the SiO etching amount is 36.1 [nm/2 min]. Meanwhile, in the Example, when the LF power is 300 W (e.g., the phase Ph3b), the SiO etching amount is 63.2 [nm/2 min], and when the LF power is 50 W (e.g., the phase Ph4b), the SiO etching amount is 15.2 [nm/2 min]. When the SiO etching amount is multiplied by the duty indicating the ratio of the supply time of the LF power within one cycle (ON/(ON+OFF)), the total SiO etching amount is 18.1 [nm/duty %] in the Reference Example. Meanwhile, in the Example, when the LF power is 300 W (e.g., the phase Ph3b), the total SiO etching amount is 15.8 [nm/duty %], and when the LF power is 50 W (e.g., the phase Ph4b), the total SiO etching amount is 3.8 [nm/duty %], so that the sum of two becomes 19.6 [nm/duty %]. Accordingly, the etching rate is faster in the Example where the processing is performed at multiple power levels, than in the Reference Example.

[Modification]

In the embodiment described above, in the supply pattern 60b, the power level of the phase Ph3b of the phases Ph3b and Ph4b, which supply the bias RF signal, is high, and the power level of the phase Ph4b is lower than the phase Ph3b. However, the relationship between the power levels of the phases Ph3b and Ph4b may be changed. That is, the distribution of the RF power of LF (LF power) may be changed.

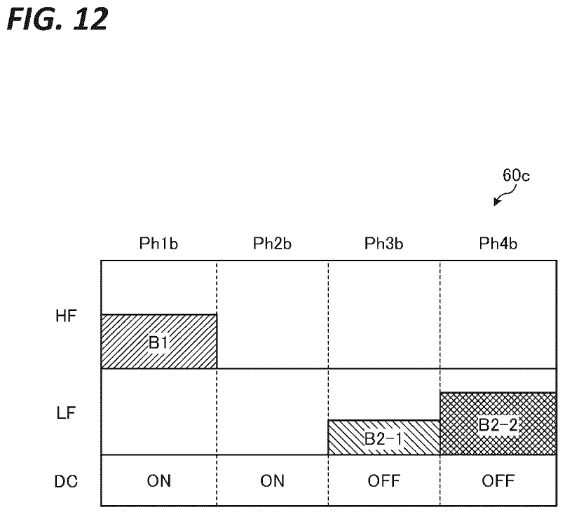

FIG. 12 is a view illustrating an example of one cycle of an RF signal in a modification. In a supply pattern 60c illustrated in FIG. 12, HF is supplied at a power level B1 (a first power level) in the phase Ph1b, and HF and LF are stopped in the phase Ph2b. Further, LF is supplied at a power level B2-1 (a second power level) in the phase Ph3b, and supplied at a power level B2-2 (a third power level) in the phase Ph4b, but the power level B2-2 is higher than the power level B2-1. That is, in the supply pattern 60c, the magnitudes of the power levels B2-1 and B2-2 are opposite to those in the supply pattern 60b illustrated in FIG. 4B. That is, the power level B2-1 (the second power level) is lower than the power level B2-2 (the third power level).

### Experiment Results of Modification

Next, experimental results of the modification will be described using FIGS. 13A and 13B. FIG. 13A is a view illustrating an example of experimental results in a case where the distribution of the RF power of LF is changed. FIG. 13B is a view illustrating the measurement parts for the etching depth d1, the mask residual amount r1, the bottom angle θ, the top critical dimension (TCD), and the bottom critical dimension (BCD). Further, in FIG. 13B, an SiON layer 65, which is an oxidized layer of the silicon nitride film, is formed around the mask (e.g., SiN). The process conditions in FIG. 13A are the same as those in FIG. 6A of the embodiment described above, except for the distribution of the LF power. FIG. 13A represents experimental results in a case where the distribution of the power levels B2-1 and B2-2 in the phases Ph3b and Ph4b is changed in Conditions A to F. Condition A represents the same conditions as those in FIG. 6A, that is, the case where the power level B2-1 of the phase Ph3b is 300 W, and the power level B2-2 of the phase Ph4b is 50 W. In FIG. 13A, the LF power distribution field represents 300 W/50 W in an order of the power levels B2-1 and B2-2.

Each of Conditions B to F also represents the LF power distribution in the same form in an order of the power levels B2-1 and B2-2. Condition B represents 250 W/100 W, Condition C represents 200 W/150 W, Condition D represents 175 W/175 W, Condition E represents 100 W/250 W, and Condition F represents 50 W/300 W. The LF effective power is 87.5 W in common in all of Conditions A to F.

The etching time is 416.7 seconds for Condition A, 487.6 seconds for Condition B, 515.8 seconds for Condition C, 452.0 seconds for Condition D, 558.8 seconds for Condition E, and 556.1 seconds for Condition F. The mask residual amount r1 is 24.9 nm for Condition A, 22.2 nm for Condition B, 21.7 nm for Condition C, 20.5 nm for Condition D, 19.7 nm for Condition E, and 22.4 nm for Condition F. The etching depth d1 is 40.9 nm for Condition A, 41.3 nm for Condition B, 43.0 nm for Condition C, 40.6 nm for Condition D, 36.3 nm for Condition E, and 32.3 nm for Condition F.

ΔCD, which is a difference between TCD and BCD (TCD−BCD) of Fin, is 3.5 nm for Condition A, 2.6 nm for Condition B, 2.5 nm for Condition C, 2.5 nm for Condition D, 1.5 nm for Condition E, and 1.4 nm for Condition F. In the cross section, the bottom angle θ is 87.55° for Condition A, 88.20° for Condition B, 88.40° for Condition C, 88.24° for Condition D, 88.80° for Condition E, and 88.75° for Condition F. From the experimental results in FIG. 13A, Condition F, which is closest to the vertical shape, is the best in shape controllability to make the bottom shape of a recess (trench) rectangular, but the etching time increases. Meanwhile, Condition A exhibits the largest mask residual amount r1. Therefore, processing conditions may be appropriately applied from Conditions A to F according to required characteristics such as the shape controllability and the aspect ratio of a recess.

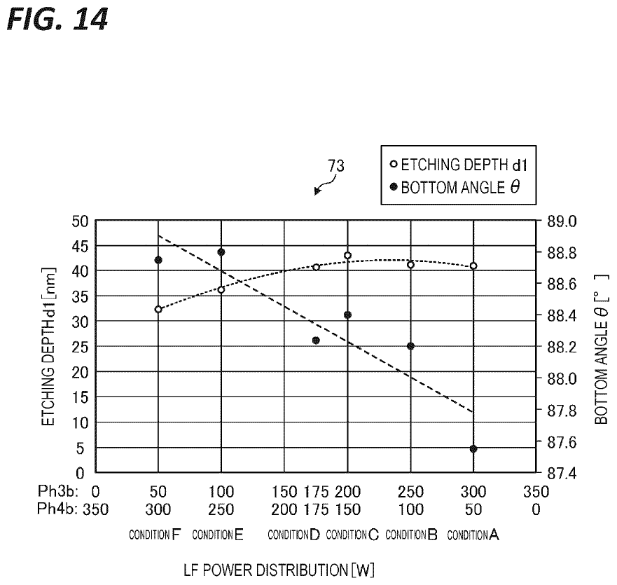

FIG. 14 is a view illustrating an example of a graph representing trend data in a case where the distribution of the RF power of LF is changed. The graph 73 illustrated in FIG. 14 relates to the etching depth d1 and the bottom angle θ among the experimental results illustrated in FIG. 13A. As represented in the graph 73, it may be seen that the bottom angle θ exhibits the trend to become vertical from Condition A toward Condition F according to the distribution of the LF power. Meanwhile, it may be seen that the etching depth d1 in Conditions E and F is slightly shallower than that in Conditions A to D, but does not exhibit the same level of trend as the bottom angle θ. Accordingly, it may be seen that the shape controllability improves in the supply pattern, in which the power level of the phase Ph4b is higher than the power level of the phase Ph3b, as in Conditions E and F.

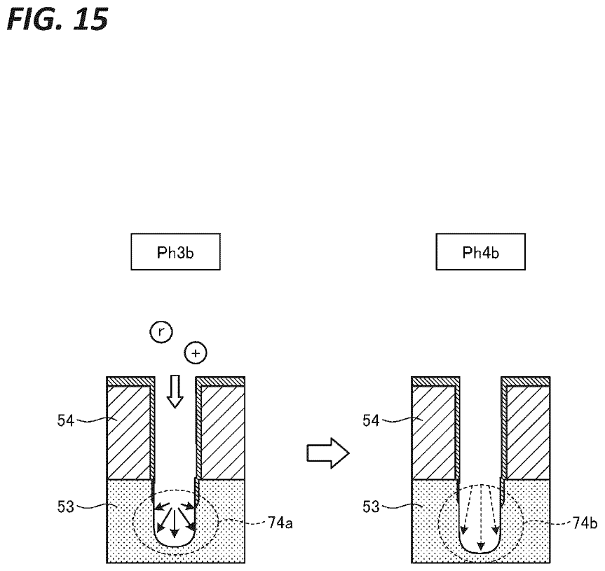

FIG. 15 is a view illustrating an example of a shape control model in the modification. FIG. 15 illustrates a shape control model in the phases Ph3b and Ph4b of the modification. In the phase Ph3b, Ar ions generated by second plasma are drawn into the bottom of the recess of the silicon oxide film 53 through the opening of the mask 54 by the bias potential, so that the etching progresses as represented in the state 74a. At this time, in the phase Ph3b, since the power level of the bias RF signal is low, the ion energy of the Ar ions generated by the second plasma decreases, and the incident angle increases, so that the shape of the bottom of the recess (bottom shape) of the silicon oxide film 53 is widened. In the subsequent phase Ph4b, since the power level of the bias RF signal increases, the ion energy of the Ar ions generated by the second plasma also increases, and the etching rate becomes faster than the phase Ph3b. In this case, as illustrated in the state 74b, the shape controllability to make the bottom shape of the recess of the silicon oxide film 53 rectangular improves as compared to the supply pattern 60b illustrated in FIG. 7B.

According to an embodiment of the present disclosure, a plasma processing apparatus includes: a chamber (e.g., the plasma processing chamber 10); a substrate support 11 disposed in the chamber and including a lower electrode; an upper electrode disposed above the substrate support 11; a first RF power supply (e.g., the first RF generator 31a) electrically connected to the upper electrode and configured to generate a first RF signal, in which the first RF signal has a first power level during a first state within a repeating period and a zero power level during a second state, a third state, and a fourth state within the repeating period; a second RF power supply (e.g., the second RF power supply) electrically connected to the lower electrode and configured to generate a second RF signal, in which the second RF signal has a zero power level during the first and second states, a second power level during the third state, and a third power level during the fourth state; and a DC power supply (e.g., the second DC generator 32b) electrically connected to the upper electrode and configured to generate a DC signal. As a result, an etching may be performed, which implements both the improvement of selection ratio, emission property, and shape controllability and the reduction of process time.

According to the embodiment, the DC signal has a constant voltage level with a negative polarity during the first, second, third, and fourth states. As a result, the carbon composition ratio of the CF deposit, which is the reaction product (e.g., deposit), may be further increased.

According to the embodiment, the DC signal has a first voltage level with a negative polarity during the first and second states and a second voltage level during the third and fourth states, and an absolute value of the second voltage level is smaller than an absolute value of the first voltage level. As a result, the carbon composition ratio of the CF deposit, which is the reaction product (e.g., deposit), may be further increased, and it is possible to contribute to the improvement of mask selection ratio and CD controllability.

According to the embodiment, the second voltage level has a zero voltage level. As a result, the carbon composition ratio of the CF deposit, which is the reaction product (e.g., deposit), may be further increased, and it is possible to contribute to the improvement of mask selection ratio and CD controllability.

According to the embodiment, the first voltage level has a sequence of negative DC pulses having a pulse frequency in a range of 1 kHz to 100 kHz. As a result, the carbon composition ratio of the CF deposit, which is the reaction product (e.g., deposit), may be further increased, and it is possible to contribute to the improvement of mask selection ratio and CD controllability.

According to the embodiment, the second power level is higher than the third power level. As a result, the bottom shape of a recess (trench) may be made tapered.

According to the embodiment, the second power level is lower than the third power level. As a result, the bottom shape of a recess (trench) may be made rectangular (vertical).

According to the embodiment, the repeating period is equal to or shorter than 100 milliseconds. As a result, the damage to the mask may be reduced, and the selection ratio may be improved.

According to the embodiment, the repeating period has a repeating frequency in a range of 10 Hz to 100 kHz. As a result, the damage to the mask may be reduced, and the selection ratio may be improved.

According to the embodiment a period of the second state is equal to or shorter than 50% of the repeating period. As a result, the selection ratio and the etching rate may be improved.

According to the embodiment, a period of the first state is the same as a period of the second state. As a result, the radical/ion ratio may be controlled in a medium range, and the production amount of deposit and the selection ratio may be controlled.

According to the embodiment, a period of the first state is longer than a period of the second state. As a result, the radical/ion ratio may be controlled in a small range, and the production amount of deposit and the selection ratio may be controlled.

According to the embodiment, a period of the first state is shorter than a period of the second state. As a result, the radical/ion ratio may be controlled in a large range, and the production amount of deposit and the selection ratio may be controlled.

According to the embodiment, the second power level is higher than the third power level, and a period of the third state is the same as a period of the fourth state. As a result, the etching amount in the depth direction may be increased, so that the etching amount in the lateral direction at the bottom may be suppressed. Further, the bottom shape may be made tapered.

According to the embodiment, the second power level is higher than the third power level, and a period of the third state is longer than a period of the fourth state. As a result, the etching amount in the depth direction may be increased, so that the etching amount in the lateral direction at the bottom may be suppressed. Further, the bottom shape may be made tapered.

According to the embodiment, the second power level is higher than the third power level, and a period of the third state is shorter than a period of the fourth state. As a result, the etching amount in the depth direction may be suppressed, so that the etching amount in the lateral direction at the bottom may be increased. As a result, the bottom may be made rectangular (vertical).

According to the embodiment, the second power level is lower than the third power level, and a period of the third state is the same as a period of the fourth state. As a result, the etching amount in the depth direction may be suppressed, so that the etching amount in the lateral direction at the bottom may be increased. Further, the bottom shape may be made rectangular (vertical).

According to the embodiment, the second power level is lower than the third power level, and a period of the third state is longer than a period of the fourth state. As a result, the etching amount in the depth direction may be suppressed, so that the etching amount in the lateral direction at the bottom may be increased. Further, the bottom shape may be made rectangular (vertical).

According to the embodiment, the second power level is lower than the third power level, and a period of the third state is shorter than a period of the fourth state. As a result, the etching amount in the depth direction may be further increased, so that the etching amount in the lateral direction at the bottom may be suppressed. Further, the bottom shape may be made tapered.

According to the embodiment, a period of the first state and a period of the second state are in a range of 0.5 microseconds to 90 milliseconds. As a result, the radical/ion ratio may be controlled, and the production amount of deposit and the selection ratio may be controlled.

According to the embodiment, a period of the third state and a period of the fourth state are in a range of 0.5 microseconds to 90 milliseconds. As a result, the bottom shape of a recess (trench) may be controlled.

According to the embodiment, a period of the first state and a period of the second state are in a range of 5% to 90% of the repeating period. As a result, the radical/ion ratio may be controlled, and the production amount of deposit and the selection ratio may be controlled.

According to the embodiment, a period of the third state and a period of the fourth state are in a range of 5% to 90% of the repeating period. As a result, the bottom shape of a recess (trench) may be controlled.

According to another embodiment of the present disclosure, a radio frequency (RF) system 31 includes: a first RF generator (e.g., the first RF generator 31a) configured to generate a first RF signal, in which the first RF signal has a first power level during a first state within a repeating period and a zero power level during a second state, a third state, and a fourth state within the repeating period; and a second RF generator (e.g., the second RF generator 31b) configured to generate a second RF signal, in which the second RF signal has a zero power level during the first and second states, a second power level during the third state, and a third power level during the fourth state. As a result, an etching may be performed, which implements both the improvement of selection ratio, emission property, and shape controllability and the reduction of process time.

In the embodiments above, the capacitively coupled plasma processing apparatus 1 is described as an example, which performs a processing such as etching on a substrate W using capacitively coupled plasma as a plasma source. However, the present disclosure is not limited thereto. As long as the apparatus performs a processing on a substrate W using plasma, the plasma source is not limited to the capacitively coupled plasma, and any plasma source such as inductively coupled plasma, microwave plasma, and magnetron plasma may be used.

According to the present disclosure, an etching may be performed, which implements both the improvement of selection ratio, etching rate, and shape controllability and the reduction of process time.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber;
a substrate support disposed in the chamber and including a lower electrode;
an upper electrode disposed above the substrate support;
a first RF power supply electrically connected to the upper electrode and configured to generate a first RF signal, the first RF signal having a first power level during a first state within a repeating period and a zero power level during a second state, a third state, and a fourth state within the repeating period;
a second RF power supply electrically connected to the lower electrode and configured to generate a second RF signal, the second RF signal having a zero power level during the first and second states, a second power level during the third state, and a third power level during the fourth state; and
a DC power supply electrically connected to the upper electrode and configured to generate a DC signal.

2. The plasma processing apparatus according to claim 1, wherein the DC signal has a constant voltage level with a negative polarity during the first, second, third, and fourth states.

3. The plasma processing apparatus according to claim 1, wherein the DC signal has a first voltage level with a negative polarity during the first and second states and a second voltage level during the third and fourth states, and an absolute value of the second voltage level is smaller than an absolute value of the first voltage level.

4. The plasma processing apparatus according to claim 3, wherein the second voltage level has a zero voltage level.

5. The plasma processing apparatus according to claim 3, wherein the first voltage level has a sequence of negative DC pulses having a pulse frequency in a range of 1 kHz to 100 kHz.

6. The plasma processing apparatus according to claim 1, wherein the second power level is higher than the third power level.

7. The plasma processing apparatus according to claim 1, wherein the second power level is lower than the third power level.

8. The plasma processing apparatus according to claim 1, wherein the repeating period is equal to or shorter than 100 milliseconds.

9. The plasma processing apparatus according to claim 1, wherein the repeating period has a repeating frequency in a range of 10 Hz to 100 kHz.

10. The plasma processing apparatus according to claim 1, wherein a period of the second state is equal to or shorter than 50% of the repeating period.

11. The plasma processing apparatus according to claim 1, wherein a period of the first state is equal to a period of the second state.

12. The plasma processing apparatus according to claim 1, wherein a period of the first state is longer than a period of the second state.

13. The plasma processing apparatus according to claim 1, wherein a period of the first state is shorter than a period of the second state.

14. The plasma processing apparatus according to claim 6, wherein a period of the third state is equal to a period of the fourth state.

15. The plasma processing apparatus according to claim 6, wherein a period of the third state is longer than a period of the fourth state.

16. The plasma processing apparatus according to claim 6, wherein a period of the third state is shorter than a period of the fourth state.

17. The plasma processing apparatus according to claim 7, wherein a period of the third state is equal to a period of the fourth state.

18. The plasma processing apparatus according to claim 7, wherein a period of the third state is longer than a period of the fourth state.

19. The plasma processing apparatus according to claim 7, wherein a period of the third state is shorter than a period of the fourth state.

20. The plasma processing apparatus according to claim 1, wherein a period of the first state is in a range of 0.5 microseconds to 90 milliseconds.

21. The plasma processing apparatus according to claim 20, wherein a period of the second state is in a range of 0.5 microseconds to 90 milliseconds.

22. The plasma processing apparatus according to claim 21, wherein a period of the third state is in a range of 0.5 microseconds to 90 milliseconds.

23. The plasma processing apparatus according to claim 22, wherein a period of the fourth state is in a range of 0.5 microseconds to 90 milliseconds.

24. The plasma processing apparatus according to claim 1, wherein a period of the first state is in a range of 5% to 90% of the repeating period.

25. The plasma processing apparatus according to claim 24, wherein a period of the second state is in a range of 5% to 90% of the repeating period.

26. The plasma processing apparatus according to claim 25, wherein a period of the third state is in a range of 5% to 90% of the repeating period.

27. The plasma processing apparatus according to claim 26, wherein a period of the fourth state is in a range of 5% to 90% of the repeating period.

28. A radio frequency (RF) system comprising:
a first RF generator configured to generate a first RF signal, the first RF signal having a first power level during a first state within a repeating period and a zero power level during a second state, a third state, and a fourth state within the repeating period; and
a second RF generator configured to generate a second RF signal, the second RF signal having a zero power level during the first and second states, a second power level during the third state, and a third power level during the fourth state.

29. The RF system according to claim 28, wherein the second power level is higher than the third power level.

30. The RF system according to claim 28, wherein the second power level is lower than the third power level.

31. The RF system according to claim 28, wherein the repeating period is equal to or shorter than 100 milliseconds.

32. The RF system according to claim 28, wherein the repeating period has a repeating frequency in a range of 10 Hz to 100 kHz.

33. The RF system according to claim 28, wherein a period of the second state is equal to or shorter than 50% of the repeating period.
